(19) United States
(12) Patent Application Publication
(10) Pub. No.: US 2015/0181760 A1
(43) Pub. Date: Jun. 25, 2015

(54) AXIALLY ALIGNED ELECTRONIC CHASSIS

(71) Applicant: Pi-Coral, Inc., San Jose, CA (US)

(72) Inventor: Donpaul C. Stephens, Houston, TX (US)

(21) Appl. No.: 14/639,595

(22) Filed: Mar. 5, 2015

Related U.S. Application Data
(63) Continuation of application No. PCT/US2013/058544, filed on Sep. 6, 2013.
(60) Provisional application No. 61/697,711, filed on Sep. 6, 2012.
(60) Provisional application No. 61/798,395, filed on Mar. 15, 2013.
(60) Provisional application No. 61/798,800, filed on Mar. 15, 2013.

(51) Int. Cl. H05K 7/20; H05K 3/36

(52) U.S. Cl. CPC H05K 7/20145; H05K 7/20172; H05K 3/368

(57) ABSTRACT

A technique for housing printed circuit board assemblies (PCAs) includes providing a set of backplane or midplane boards that are oriented orthogonally and edge-to-edge with an array of PCAs such that air introduced at one end of the chassis passes in a straight line course through the PCAs and through the backplane or midplane boards with no substantial bends or changes in direction.

### CROSS-REFERENCE TO RELATED APPLICATIONS

This is a continuation of PCT/US2013058544, filed Sep. 6, 2013, which claims priority to U.S. provisional application No. 61/697,711, filed Sep. 6, 2012, U.S. provisional application No. 61/798,395, filed Mar. 15, 2013, and U.S. provisional application No. 61/798,800, filed Mar. 15, 2013. The contents and teachings of these related applications are incorporated herein by reference as if set forth explicitly.

### BACKGROUND

Many diverse electronic applications require the use of multiple printed circuit board assemblies (PCAs). The PCAs are commonly housed within one or more chassis. The chassis may be free-standing or installed in racks. Data centers and other facilities typically include many racks, each holding multiple chassis. The racks may be provided together in rooms, which may be environmentally controlled for temperature and humidity.

Conventional chassis include, among other elements, backplanes, card guides, and fans. PCAs having edge connectors are typically inserted into a front opening of a chassis and along card guides, which direct the PCAs toward the backplane, where their edge connectors mate with backplane connectors. As its name implies, the backplane is typically a planar circuit board assembly with many connectors for receiving PCAs plugged into the chassis. The backplane is oriented orthogonally to the PCAs and facing the PCAs (i.e., the backplane forms an extended back surface behind the PCAs). The backplane typically includes a great many conductive and insulating layers, for conveying electrical signals and power among the different PCAs that connect to it. To cool the PCAs, the chassis typically includes fans, which force air between the PCAs. Generally, air is drawn in from the front of the chassis and directed upwardly, between the PCAs. Heated air then exhausts through the rear at the top of the chassis.

Some chassis include midplanes instead of backplanes. In these arrangements, the midplanes act essentially as double-sided backplanes. PCAs may be inserted from the fronts of such chassis to engage the midplanes from one side, and PCAs may also be inserted from the backs of such chassis to engage the midplanes from the other side. Such chassis may be cooled essentially as described above, with air entering the front and directed upwardly, now through two sets of circuit boards. Spent air is exhausted through the rear.

### SUMMARY

Unfortunately, cooling PCAs in conventional chassis can be complex. For example, air introduced at the front of a chassis must typically make two right-angle turns before it is exhausted through the rear. Such turns tend to slow airflow, requiring more powerful fans than would otherwise be needed. In addition, conventional chassis often require additional vertical space for providing an intake plenum and an outlet plenum, for receiving and exhausting air and for effecting the required right-angle turns. Resulting chassis are thus typically larger than they might otherwise need to be.

In contrast with conventional chassis, an improved technique for housing printed circuit board assemblies (PCAs) includes providing a set of backplane or midplane boards that are oriented orthogonally and edge-to-edge with an array of PCAs such that air introduced at one end of the chassis passes in a straight line course through the PCAs and through the backplane or midplane boards with no substantial bends or changes in direction. Each of the backplane/midplane boards connects to multiple PCAs to allow conduction of electronic signals and power between PCAs. In a midplane arrangement, midplane boards have two ends and PCAs connect to the midplane boards from both ends thereof. The midplane boards may thus allow conduction of electronic signals and power both among PCAs on each side of the midplane and between PCAs on opposite sides.

Advantageously, chassis constructed in this arrangement may be operated with lower power fans, which generate less acoustic noise and consume less electricity. Such chassis may often be made smaller than conventional chassis, as no intake or outlet plena are required. In some arrangements, the backplane/midplane boards are spaced apart and fans are provided in the spaces between them. An effective sandwiching of backplane/midplane boards with fans makes efficient use of available space. Further, backplane/midplane boards according to this arrangement typically have less restrictive routing requirements than do conventional backplanes and midplanes, enabling them to be made thinner and less expensively than circuit boards for conventional backplanes and midplanes.

### BRIEF DESCRIPTION OF THE SEVERAL VIEWS OF THE DRAWINGS

The foregoing and other features and advantages will be apparent from the following description of particular embodiments of the invention, as illustrated in the accompanying drawings, in which like reference characters refer to the same parts throughout the different views. The drawings are not necessary to scale, emphasis instead being placed upon illustrating the principles of various embodiments of the invention. In the accompanying drawings,

FIG. 1 is an isometric view of an example chassis according to an embodiment of the invention, with covers removed to expose internal components;

FIG. 2 is an isometric view of the example chassis of FIG. 1 from a different perspective;

FIG. 3 is another isometric view of the example chassis of FIG. 1, but with a circuit board assemblies (PCAs) at the rear of the chassis removed to reveal midplane connectors;

FIG. 4 is yet another isometric view of the example chassis of FIG. 1, but shown with covers in place and revealing openings at a side of the chassis for inserting and removing fan trays;

FIG. 5 is yet another isometric view of the example chassis of FIG. 1, which is similar to FIG. 4 but shows fan trays being inserted or removed through the openings at the side of the chassis;

FIG. 6 is an isometric view of an example midplane assembly, which includes two midplane boards fastened together; and

FIG. 7 is a flowchart showing an example process for housing PCAs.

### DETAILED DESCRIPTION OF THE INVENTION

Embodiments of the invention will now be described. It is understood that such embodiments are provided by way of example to illustrate various features and principles of the invention, and that the invention hereof is broader than the specific example embodiments disclosed.

An improved technique for housing printed circuit board assemblies (PCAs) includes providing a set of backplane or midplane boards that are oriented orthogonally and edge-to-edge with an array of PCAs such that air introduced at one end of the chassis passes in a substantially straight line through the PCAs and through the backplane or midplane boards with no substantial bends or changes in direction.

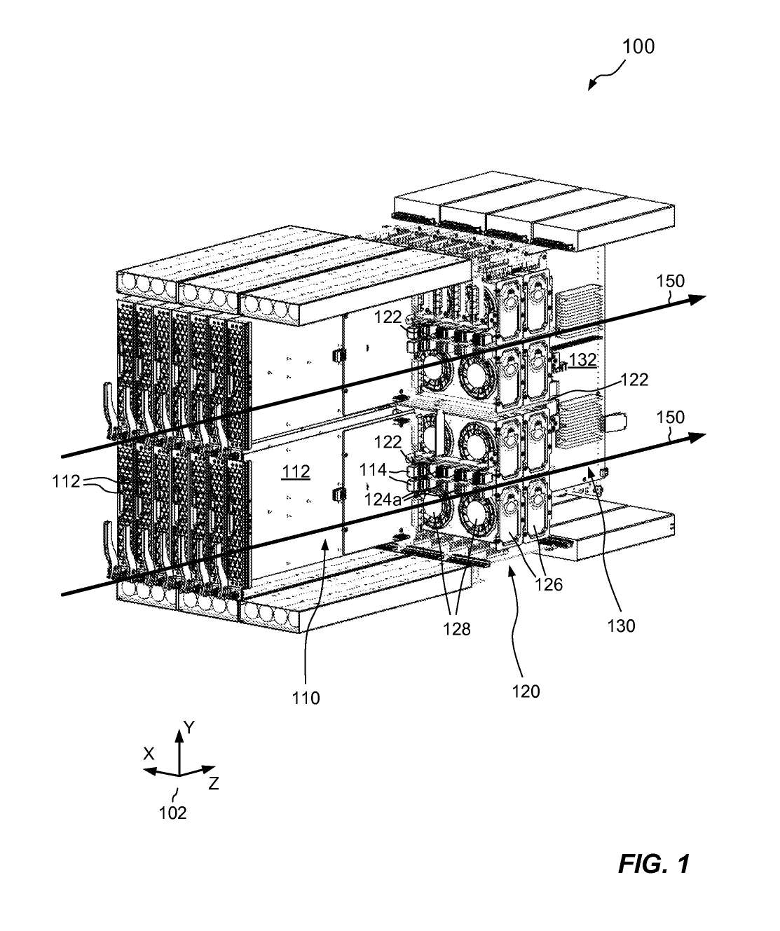

FIGS. 1-5 show various views of an example chassis 100 constructed in accordance with an embodiment of the invention. Starting with FIG. 1, it is seen that covers of the chassis 100 have been removed to reveal internal components. The chassis 100 is seen to include a first region 110, a second region 120, and a third region 130. The regions 110, 120, and 130 are spaces within the chassis 100 for containing various components. As shown, the first region 110 includes a first array of one of more circuit board assemblies (PCAs) 112, the second region 120 includes a second array of one or more PCAs 122 (e.g., midplane boards, as best seen in FIG. 6), and the third region 130 includes a third array of one or more PCAs 132.

A legend 102 indicates relative orientation in mutually orthogonal X-Y-Z space. The PCAs 112 and 132 can thus be seen as oriented parallel to a Y-Z plane of the X-Y-Z space, while the PCAs 122 can be seen as oriented parallel to an X-Z plane of the X-Y-Z space. The first, second, and third regions 110, 120, and 130 are seen to extend successively back in a positive Z direction.

In the particular example shown, the first array of PCAs 112 are provided as half-height PCAs (i.e., they occupy half the vertical height for housing PCAs in the region 110). However, this is merely an example, as the PCAs may alternatively occupy some other fraction of the total height or the entire height. In some embodiments, the PCAs in the upper half of the first region 110 can be regarded as yet another array of PCAs, which interconnects with other components of the chassis 100 in a similar way to the first array of PCAs 112.

The second region 120 is seen to further include multiple fan trays 126, with each fan tray 126 including multiple fans 128. A total of eight fan trays 126 are shown; however, any suitable number may be provided. The fan trays 126 are positioned among the PCAs 122 within the second region 120. For example, two fan trays 126 are shown disposed between upper and lower pairs of PCAs 122.

In the example shown, six PCAs 122 are provided in second region 120. Any suitable number of PCAs 122 may be included, however, as best suited for the particular implementation. The PCAs 122 may be provided in pairs, as shown (see FIG. 6), or the PCAs 122 may be provided separately. In some examples, additional PCAs 122 are provided at the bottom of the region 120 (e.g., beneath the lower-most fan tray 126), at the top of the region 120 (e.g., above the upper-most fan tray 126), and/or at some other vertical location.

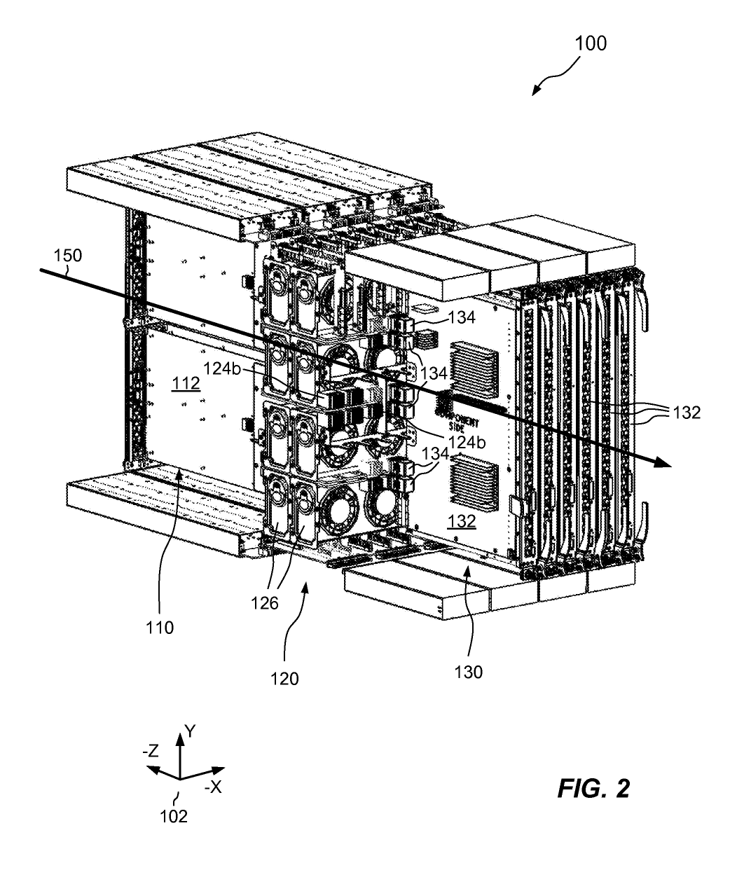

With the orientations of PCAs 112, 122, and 132 as shown, the PCAs 122 in the second region 120 can be seen to contact the PCAs 112 and 132 in the first and third regions 110 and 130 edge-to-edge and orthogonally, such that each of the PCAs 122 cuts across multiple PCAs 112 and 132 and forms connections therewith. For example, the PCAs 112 in the first region 110 include connectors 114, which engage with connectors 124a on the PCAs 122. Similarly, the PCAs 132 include connectors 134 (best seen in FIG. 2), which engage connectors 124b on the PCAs 122. The array of PCAs 122 can thus be regarded as forming a midplane, and the individual PCAs 122 can be regarded as midplane boards. PCAs 112 and 132 can be inserted along card guides into designated locations within the chassis 100, with the connectors 114 engaging the connectors 124a on the PCAs 122 (midplane boards) and the connectors 134 engaging connectors 124b on the PCAs 122.

In some examples, the chassis 100 includes first and second regions 110 and 120 only, with no third region 130 provided. In such examples, the array of PCAs 122 in the second region 120 can be regarded as forming a backplane, with the individual PCAs 122 forming backplane cards.

The PCAs 122 typically include conductive traces, ground planes, power planes, etc., for conveying electrical signals between different PCAs. Different implementations have different requirements, however, and the PCAs 122 can be provisioned with traces, planes, and even electrical components as needed to suit the requirements of particular use cases. Typically, the PCAs 122 include conductive traces that establish electrical connections between different PCAs 112 in the first region 110, between different PCAs 132 in the third region 130, and between the PCAs 112 and the PCAs 132. It is not required, however, that all PCAs 122 provide all of these connections. For example, the illustrated arrangement shows PCAs 122 near the vertical middle of the chassis 100 provided with connectors 124b for mating with connectors 134 on the PCAs 132 but no connectors 124a for mating with PCAs 112. Other PCAs 122 include both sets of connectors. The “middle” PCAs 122 can thus function as backplane boards with respect the PCAs 132 in the third region 130, while in the same chassis 100 other PCAs 122 (e.g., those nearer to top and bottom) function as midplane boards.

Because the PCAs 122 have a length, signal routing is often more easily achieved than when using conventional backplanes and midplanes, since the entire length of the PCAs 122 may be available for signal routing. In some examples, the PCAs 122 may be made longer or shorter, based on routing requirements, desired numbers of PCA layers, available space, cost, and other factors. The length of PCAs 122 thus provides an additional degree of freedom, which designers may consider when developing chassis for particular applications.

With the arrangement shown, it is also evident that airflow 150 can be established in the Z direction of the X-Y-Z space without any substantial bends or turns. For example, air enters the first region 110 of the chassis 100, passes among and between the PCAs 112 in the first region 110, passes through the fans 128 in the second region 120, and passes among and between the PCAs 132 in the third region 130, before exiting the third region 130 at the rear of the chassis 100. Because all PCAs 112, 122, and 132 are oriented parallel to the direction of airflow 150 (i.e., parallel to the Z-axis), air passes over and through the PCAs 112, 122, and 132 substantially unimpeded. It should be understood that electronic parts, connectors, heatsinks, fan frames, and other components may interfere slightly with airflow 150 and thus alter the flow of packets of air on a small scale. Such packets of air may thus take minor turns as they pass around and between components of the chassis 100. Obstructions like these are expected and desired, however, as they promote cooling of components. But airflow 150 when viewed in the aggregate maintains a straight line course as it passes from the front of the chassis 100 to the back. Although the direction of airflow 150 is shown as extending front-to-back, example embodiments work equally well with the direction of airflow 150 reversed.

The chassis 100 provides a number of distinct advantages over conventional chassis. For example, because airflow 150 follows a straight line course, there is no need for the fans 128 to force large amounts of air around corners. Thus, the fans 128 can be made significantly smaller and/or lower power, and/or fewer fans can be provided. The chassis 100 can thus consume less electricity than conventional chassis. Further, the direct path of airflow 150 avoids the need for intake and/or outlet plena, thus allowing the chassis 100 to be made smaller than conventional chassis. Further still, the PCAs 122 used as midplane/backplane boards can often be manufactured less expensively than conventional backplane/midplane cards, with fewer layers and fewer routing constraints. Together, these factors can significantly reduce initial cost of the chassis 100. They can also reduce operating costs and failure rates of the chassis 100 as compared with conventional designs.

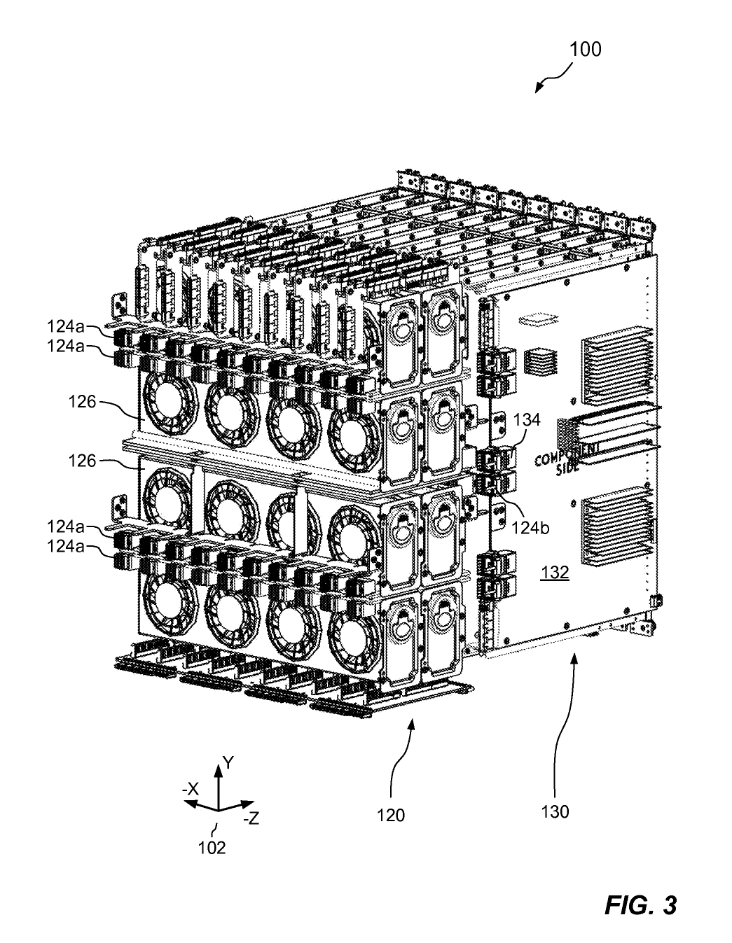

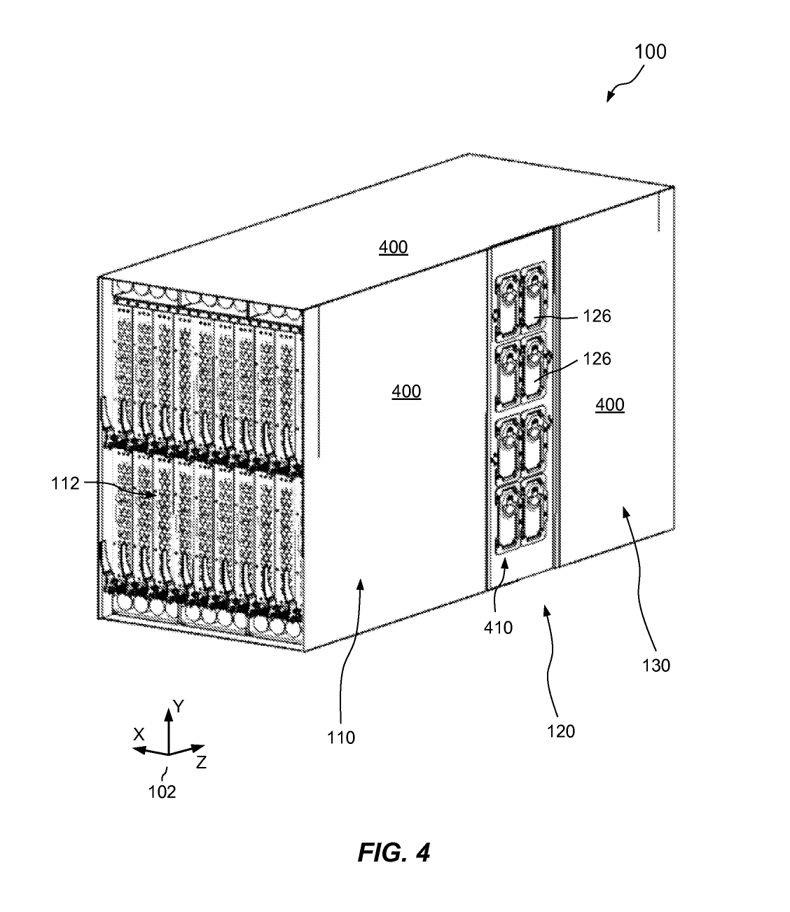

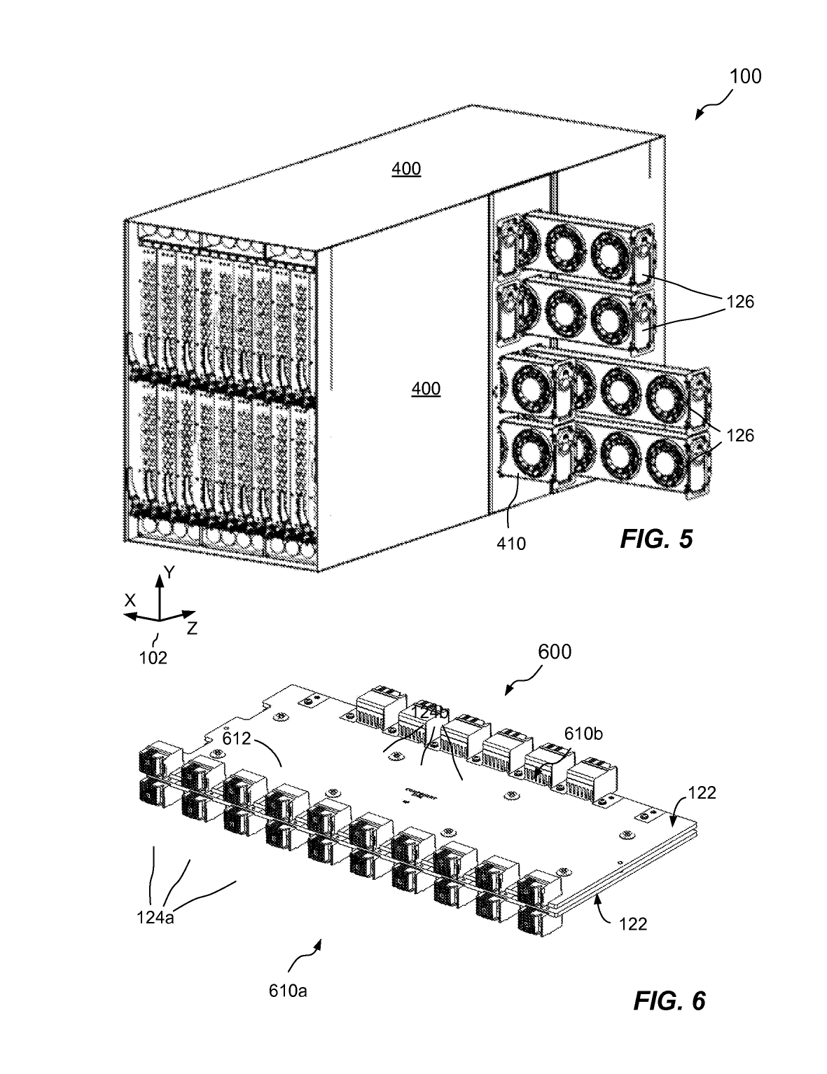

Other figures show additional views of the chassis 100. FIG. 2 shows the chassis 100 from the rear, providing a view of connectors 124b on the PCAs 122 and their mating with connectors 134 on the PCAs 132. FIG. 3 shows the chassis 100 with the first array of PCAs 112 removed, thus also exposing connectors 124a on the PCAs 122. FIG. 4 shows the chassis 100 with covers 400 in place. It can be seen from FIG. 4 that the chassis 100 includes openings 410 at a side of the chassis 100 for allowing fan trays 126 to be inserted and withdrawn. FIG. 5 shows several fan trays 126 partially withdrawn through the openings 410 at the side of the chassis 100. By providing the fan trays 126 in the second region 120 and allowing the fans to be accessed from the side of the chassis 100, the rear or the chassis 100 is kept free of fans, thus providing more space for cable management and easier access to the PCAs 132.

FIG. 6 shows an example assembly 600 that includes two PCAs 122. Each of the PCAs 122 shown in FIG. 6 has a first array of connectors 124a at a first end 610a, which connectors 124a are arranged to engage with connectors 114 (FIG. 1) on the PCAs 112 in the first region 110. Each of the PCAs 122 also has a second array of connectors 124b at a second end 610b, which connectors 124b are arranged to engage connectors 134 on the PCAs 132 in the third region 130 (FIG. 2). The two PCAs 122 shown in FIG. 6 are fastened together, e.g., using screws 612, adhesive, or some other type of fastener or material. In some examples, an insulative layer is interposed between the PCAs 122 to prevent short circuits and/or to fill air gaps. In a further example, a metal layer (not shown) is placed between the PCAs 122. The metal layer is connected or AC-coupled to an electrical ground of the chassis 100 to provide an electrostatic shield between the two PCAs 122 shown in FIG. 6. One or more insulative layers may also be provided to prevent the PCAs 122 from shorting to the shield.

In the example shown in FIG. 6, the two PCAs 122 are constructed substantially as mechanical mirror images of each other. The connectors 124a and 124b on the top PCA face up (i.e., in the positive Y direction), whereas the connectors 124a and 124b on the bottom PCA face down (i.e., in the negative Y direction), opposite the direction of connectors on the top PCA.

Providing PCAs 122 in the form of assemblies 600 makes efficient use of space in the second region 120 and helps to minimize resistance to airflow 150. It should be understood, however, that assemblies of PCAs 122 can be constructed in other ways than that shown in FIG. 6. For example, PCAs 122 with similar geometry (not mirror images) can be stacked one on top of the other in any suitable arrangement. In addition, PCAs 122 may be provided individually, separate from any assembly of multiple PCAs 122. Further, although the assembly 600 is seen to include two PCAs 122, other assemblies can be constructed that include a greater number of PCAs. The example shown is merely illustrative.

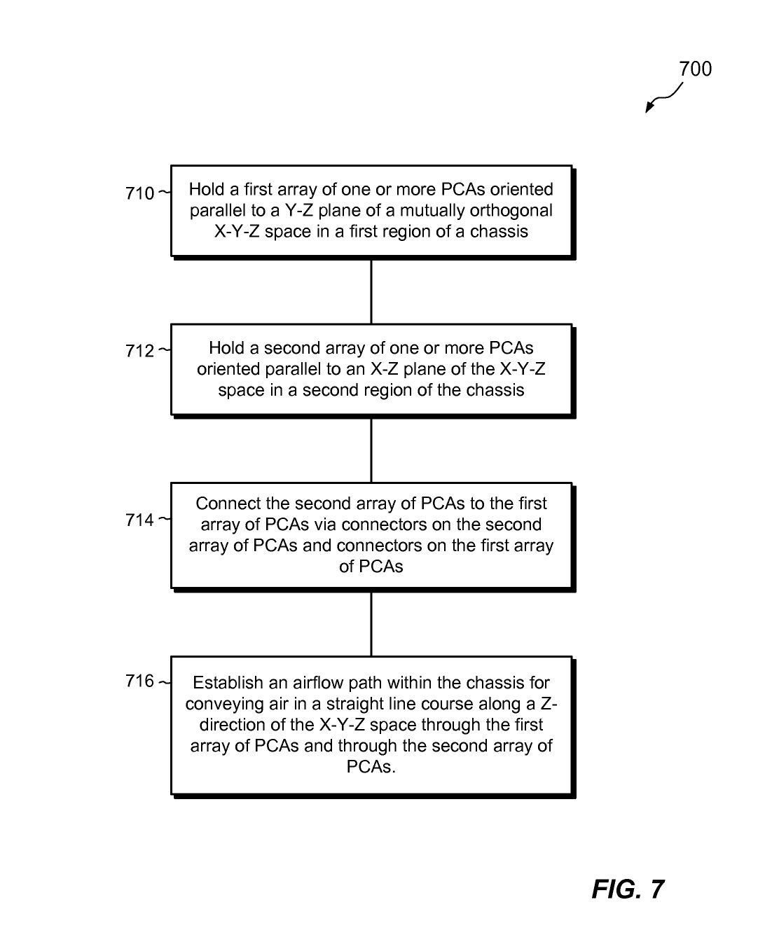

FIG. 7 shows an example process for printed circuit board assemblies (PCAs). At step 710, a first array of one or more PCAs oriented parallel to a Y-Z plane of a mutually orthogonal X-Y-Z space are held in a first region of a chassis. For example, the chassis 100 holds the first array of PCAs 112 in the first region 110.

At step 712, a second array of one or more PCAs oriented parallel to an X-Z plane of the X-Y-Z space are held in a second region of the chassis. For example, the chassis 100 holds the second array of PCAs 122 in the second region 120.

At step 714, the second array of PCAs is connected to the first array of PCAs via connectors on the second array of PCAs and connectors on the first array of PCAs. For example, the PCAs 122, forming a backplane or midplane, connect to the PCAs 112 in the first region 110 via connectors 124a mating with connectors 114.

At step 716, an airflow path is established within the chassis for conveying air in a straight line course along a Z-direction of the X-Y-Z space through the first array of PCAs and through the second array of PCAs. For example, the airflow path 150 is established, by operation of the fans 128, along a straight line course through the first array of PCAs 112 and through the second array of PCAs 122. Air may then exit from the back of the chassis 110. In some examples, a third array of PCAs 132 is provided, and airflow 150 continues in its straight line course 150 through the third array of PCAs 132.

An improved technique has been described for housing printed circuit board assemblies (PCAs). The technique includes providing a set of backplane or midplane boards (e.g., 122) that are oriented orthogonally and edge-to-edge with an array of PCAs (e.g., 112) such that air introduced at one end of the chassis 100 passes along a straight line course through the PCAs 112 and through the backplane or midplane boards 122 with no substantial bends or changes in direction. Each of the backplane/midplane boards 122 connects to multiple PCAs 112 to allow conduction of electronic signals and power between PCAs 122. In a midplane arrangement, midplane boards 122 have two ends (e.g., 610a and 610b) and PCAs 112 and 132 connect to the midplane boards 122 from both ends thereof. The midplane boards 122 may thus allow conduction of electronic signals and power both among PCAs on each side of the midplane and between PCAs on opposite sides.

As used throughout this document, the words “comprising,” “including,” and “having” are intended to set forth certain items, steps, elements, or aspects of something in an open-ended fashion. Also, as used herein and unless a specific statement is made to the contrary, the word “set” means one or more of something. Although certain embodiments are disclosed herein, it is understood that these are provided by way of example only and the invention is not limited to these particular embodiments. Further, the terms “front,” “back,” “top,” “bottom,” and so forth are used herein for convenient reference. It is understood, however, that the chassis 100 has no required orientation.

Having described certain embodiments, numerous alternative embodiments or variations can be made. For example, although the figures illustrate a midplane arrangement, with PCAs 112/132 engaging PCAs 122 that act as midplane boards, the PCAs 132 may alternatively be omitted and the PCAs 122 may act as backplane boards. Where the PCAs 122 are configured as backplane boards, no connectors 124b are needed and the PCAs 122 simply convey signals, power, etc., between different PCAs 112 in the first region 110.

The chassis 100 may be used in a wide variety of applications. Although the chassis 600 may be particularly suitable for use in data storage systems, network systems, communication systems, cloud computing systems, and automatic test systems, for example, the chassis 600 is not limited to these applications or to any application or group of applications.

The chassis 100 has been described as including various printed circuit board assemblies (PCAs). It should be understood that the PCAs may be constructed in any suitable fashion and from any suitable materials. For example, the PCAs may include alternating layers of fiberglass-reinforced epoxy (e.g. FR-4) and copper, may include wires inserted into insulating substrates, may employ polymer films or sheets, or may employ any other suitable materials.

Also, although the chassis 100 has been shown and described as forming an airflow path 150, it is understood that that chassis 100 can employ with any suitable cooling fluid, whether it be gaseous or liquid. Thus, the invention hereof is not limited to the use of air as a cooling fluid.

Further, although features are shown and described with reference to particular embodiments hereof, such features may be included and hereby are included in any of the disclosed embodiments and their variants. Thus, it is understood that features disclosed in connection with any embodiment are included as variants of any other embodiment. Those skilled in the art will therefore understand that various changes in form and detail may be made to the embodiments disclosed herein without departing from the scope of the invention.

What is claimed is:

1. A chassis for housing printed circuit board assemblies (PCAs), comprising:
first and second contiguous regions, the first region housing a first array of one or more PCAs oriented parallel to a Y-Z plane of a mutually orthogonal X-Y-space, the second region housing a second array of one or more PCAs oriented parallel to an X-Z plane of the X-Y-Z space, the second array of PCAs having connectors for connecting directly with connectors on the first array of PCAs; and
an airflow path established within the chassis for conveying air in a straight line course along a Z direction of the X-Y-Z space through the first array of PCAs and through the second array of PCAs.

2. The chassis of claim 1, further comprising a set of fans positioned within the second region among the PCAs of the second array of PCAs to induce airflow through the first array of PCAs in the Z direction.

3. The chassis of claim 2, wherein the set of fans includes at least one fan positioned between two consecutive PCAs of the second array of PCAs in the second region.

4. The chassis of claim 2, wherein the set of fans includes multiple fan trays each including multiple fans, at least one fan tray positioned between a pair of PCAs of the second array of PCAs in the second region.

5. The chassis of claim 4, further comprising a set of openings on a side of the chassis for allowing the fan trays to be inserted into the chassis along an X direction of the X-Y-Z space.

6. The chassis of claim 1, wherein each of the PCAs in the second array of PCAs has at least one connector for connecting with a connector on each of the PCAs in the first array of PCAs.

7. The chassis of claim 1, further comprising:
a third region contiguous with the second region, the third region including a third array of one or more PCAs oriented parallel to the Y-Z plane,
wherein the second array of PCAs also has connectors for connecting directly with connectors on the third array of PCAs, and
wherein the airflow path is established within the chassis for conveying air in the straight line course along the Z direction through the first array of PCAs, through the second array of PCAs, and through the third array of PCAs.

8. The chassis of claim 7, further comprising:
a set of fans positioned within the second region among the PCAs of the second array of PCAs to induce airflow through the first, second, and third arrays of PCAs in the Z direction,
wherein the set of fans includes multiple fan trays each including multiple fans, at least one fan tray positioned between two consecutive PCAs of the second array of PCAs in the second region.

9. The chassis of claim 8, further comprising a set of openings on a side of the chassis for allowing the fan trays to be withdrawn from the chassis along an X direction of the X-Y-Z space.

10. The chassis of claim 9, wherein the first region includes an additional array of PCAs spaced away from the first array of PCAs along a Y direction of the X-Y-Z space, and wherein each of the PCAs in the additional array of PCAs is oriented parallel to the Y-Z plane.

11. The chassis of claim 7, wherein the second array of PCAs includes at least one assembly, the assembly including:
a first PCA having a first end and a second end and oriented parallel to the X-Z plane; and
a second PCA having a first end and a second end and oriented parallel to the X-Z plane;
wherein the first PCA includes a first array of connectors at the first end of the first PCA and a second array of connectors at the second end of the first PCA, the first array of connectors and the second array of connectors extending from the assembly in a positive Y direction of the X-Y-Z space, and
wherein the second PCA includes a first array of connectors at the first end of the second PCA and a second array of connectors at the second end of the second PCA, the first array of connectors and the second array of connectors of the second PCA extending from the assembly in a negative Y direction of the X-Y-Z space.

12. The chassis of claim 11, wherein each of the connectors in the first array of connectors of the first PCA connects to a respective PCA in the first array of PCAs, and wherein each of the connectors in the first array of connectors of the second PCA connects to a respective PCA in the first array of PCAs.

13. The chassis of claim 12, wherein each of the connectors in the second array of connectors of the first PCA connects to a respective PCA in the third array of PCAs, and wherein each of the connectors in the second array of connectors of the second PCA connects to a respective PCA in the third array of PCAs.

14. A chassis for housing printed circuit board assemblies (PCAs), comprising:
first and second contiguous regions, the first region constructed and arranged to house a first array of multiple PCAs oriented parallel to a Y-Z plane of a mutually orthogonal X-Y-Z space, the second region housing a second array of multiple PCAs oriented parallel to an X-Z plane of the X-Y-Z space, the second array of PCAs having connectors for connecting directly with connectors on the first array of PCAs; and
an airflow path established within the chassis for conveying air in a straight line course along a Z direction of the X-Y-Z space through the first array of PCAs and through the second array of PCAs.

15. The chassis of claim 14, further comprising:
a third region contiguous with the second region, the third region constructed and arranged to house a third array of one or more PCAs oriented parallel to the Y-Z plane,
wherein the second array of PCAs also has connectors for connecting directly with connectors on the third array of PCAs, and
wherein the airflow path is established within the chassis for conveying air in the straight line course along the Z direction through the first array of PCAs, through the second array of PCAs, and through the third array of PCAs.

16. The chassis of claim 15, further comprising:
a set of fans positioned within the second region among the second array of PCAs for inducing airflow through the first, second, and third arrays of PCAs in the Z direction,
wherein the set of fans includes multiple fan trays each including multiple fans, each fan tray positioned between two consecutive PCAs of the second array of PCAs in the second region.

17. The chassis of claim 16, further comprising a set of openings on a side of the chassis for allowing the fan trays to be inserted into the chassis along an X direction of the X-Y-Z space.

18. The chassis of claim 15, wherein the second array of PCAs includes at least one assembly, the assembly including:
a first PCA having a first end and a second end and oriented parallel to the X-Z plane; and
a second PCA having a first end and a second end and oriented parallel to the X-Z plane;
wherein the first PCA includes a first array of connectors at the first end of the first PCA and a second array of connectors at the second end of the first PCA, the first array of connectors and the second array of connectors extending from the assembly in a positive Y direction of the X-Y-Z space, and
wherein the second PCA includes a first array of connectors at the first end of the second PCA and a second array of connectors at the second end of the second PCA, the first array of connectors and the second array of connectors of the second PCA extending from the assembly in a negative Y direction of the X-Y-Z space.

19. A method for housing printed circuit board assemblies (PCAs), comprising:
holding a first array of PCAs oriented parallel to a Y-Z plane of a mutually orthogonal X-Y-Z space in a first region of a chassis;
holding a second array of PCAs oriented parallel to an X-Z plane of the X-Y-Z space in a second region of the chassis;
connecting the second array of PCAs to the first array of PCAs via connectors on the second array of PCAs directly mating with connectors on the first array of PCAs; and
establishing an airflow path within the chassis for conveying air in a straight line course along a Z-direction of the X-Y-Z space through the first array of PCAs and through the second array of PCAs.

20. The method of claim 19, further comprising:
holding a third array of one or more PCAs oriented parallel to the Y-Z plane in a third region of the chassis, the third region contiguous with the second region;
connecting the second array of PCAs to the third array of PCAs via connectors on the second array of PCAs directly mating with connectors on the third array of PCAs,
wherein establishing the airflow path within the chassis includes conveying air in the straight line course along the Z direction through the first array of PCAs, through the second array of PCAs, and through the third array of PCAs.

21. The method of claim 19, further comprising inserting multiple fan trays into the chassis along an X direction such that two fan trays are disposed adjacently along a Z direction.
